(19) United States
(12) Patent Application Publication
(10) Pub. No.: US 2023/0276664 A1
(43) Pub. Date: Aug. 31, 2023

(54) DISPLAY DEVICE

(71) Applicant: SAMSUNG DISPLAY CO., LTD., Yongin-si (KR)

(72) Inventors: Yong Hwan PARK, Yongin-si (KR); Seong Jun Lee, Yongin-si (KR)

(21) Appl. No.: 18/195,608

(22) Filed: May 10, 2023

(30) Foreign Application Priority Data
Aug. 25, 2022 (KR) 10-2022-0107155

(51) Int. Cl. H10K 59/122; H10K 59/40; H10K 59/80; H10K 59/121; H10K 59/131

(52) U.S. Cl. CPC H10K 59/122; H10K 59/40; H10K 59/8792; H10K 59/8793; H10K 59/1213; H10K 59/131

(57) ABSTRACT

A display device includes: a display panel including a light emitting element layer including a pixel defining layer dividing a display area into an emission area and a non-emission area, a thin film encapsulation layer disposed on the light emitting element layer, and a shielding layer including a shielding electrode disposed on the thin film encapsulation layer that is disposed on a substrate including the display area and a non-display area; and a touch panel attached to the display panel through a first optically clear adhesive and including touch electrodes, wherein the light emitting element layer includes a light emitting layer corresponding to the emission area, and the shielding electrode overlaps the non-emission area.

### CROSS-REFERENCE TO RELATED APPLICATION

The present application claims priority under 35 U.S.C. § 119(a) to Korean patent application No. 10-2022-0107155 filed on Aug. 25, 2022 in the Korean Intellectual Property Office, the disclosure of which is incorporated by reference herein in its entirety.

### TECHNICAL FIELD

Embodiments of he present invention relate to a display device.

### DISCUSSION OF RELATED ART

Recent display devices including an information input function in addition to an image display function have been under development. In general, the information input function of the display device may be implemented as a touch sensor for receiving a touch input of a user or a touch input from a predetermined tool. Typically, the touch sensor is attached to one surface of a display panel or is integrally formed with the display panel.

### SUMMARY

According to an embodiment of the present invention, a display device includes: a display panel including a light emitting element layer including a pixel defining layer dividing a display area into an emission area and a non-emission area, a thin film encapsulation layer disposed on the light emitting element layer, and a shielding layer including a shielding electrode disposed on the thin film encapsulation layer that is disposed on a substrate including the display area and a non-display area; and a touch panel attached to the display panel through a first optically clear adhesive and including touch electrodes, wherein the light emitting element layer includes a light emitting layer corresponding to the emission area, and the shielding electrode overlaps the non-emission area.

According to an embodiment of the present invention, a display device includes: a display panel including a light emitting element layer including a pixel defining layer dividing a display area into a first area and a second area, a thin film encapsulation layer disposed on the light emitting element layer, and a shielding layer including a shielding electrode disposed on the thin film encapsulation layer that is disposed on a substrate including the display area and a non-display area; a polarizer disposed on the shielding layer; and a touch panel attached to the polarizer through an optically clear adhesive and including touch electrodes, wherein the light emitting element layer includes a light emitting layer corresponding to the first area, the touch electrodes overlap the first area and the second area, and the shielding electrode includes an opaque metal and overlaps the second area.

### BRIEF DESCRIPTION OF THE DRAWINGS

The above and other features of the present invention will become more apparent by describing in further detail exemplary embodiments thereof with reference to the accompanying drawings, in which:

FIG. 1 is a diagram schematically illustrating a display device according to an embodiment of the present invention;

FIG. 2 is a schematic cross-sectional view illustrating an example of the display device of FIG. 1;

FIG. 3 is a circuit diagram illustrating an example of a pixel included in the display device of FIG. 1;

FIG. 4 is a schematic plan view illustrating an example of a portion of a touch panel included in the display device of FIG. 1;

FIG. 5 is a schematic cross-sectional view illustrating an example of the touch panel of FIG. 4 taken along a line I-I′;

FIG. 6 is a schematic cross-sectional view of an example of the touch panel of FIG. 4 taken along a line II-II;

FIG. 7 is a schematic plan view illustrating an example of a display area of the display device of FIG. 1;

FIG. 8 is a schematic cross-sectional view illustrating an example of the display area and a non-display area of the display device of FIG. 1;

FIG. 9 is a schematic cross-sectional view illustrating an example of the display area and the non-display area of the display device of FIG. 1;

FIG. 10 is a schematic cross-sectional view illustrating an example of the display area and the non-display area of the display device of FIG. 1;

FIG. 11 is a schematic cross-sectional view illustrating an example of the display area and the non-display area of the display device of FIG. 1;

FIG. 12 is a schematic cross-sectional view illustrating an example of the display area and the non-display area of the display device of FIG. 1;

FIG. 13 is a schematic cross-sectional view illustrating an example of the display area and the non-display area of the display device of FIG. 1;

FIG. 14 is a schematic plan view illustrating an example of pixels and a shielding electrode included in the display device of FIG. 1; and

FIG. 15 is a schematic plan view illustrating an example of the pixels and the shielding electrode included in the display device of FIG. 1.

### DETAILED DESCRIPTION OF THE EMBODIMENTS

Hereinafter, embodiments of the present invention are described in more detail with reference to the accompanying drawings. The same reference numerals are used for the same components in the drawings, and a repeated description of the same components may be omitted.

Since the embodiment described in the present specification is for clearly describing the spirit of the disclosure to those skilled in the art to which the disclosure pertains, the disclosure is not limited by the embodiment described in the present specification, and the scope of the present disclosure should be interpreted as including modifications or variations that do not depart from the spirit and scope of the present disclosure.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

In the present specification, when it is determined that detailed description of a known configuration or function related to the present invention may obscure the subject matter of the present invention, detailed description thereof will be omitted as necessary.

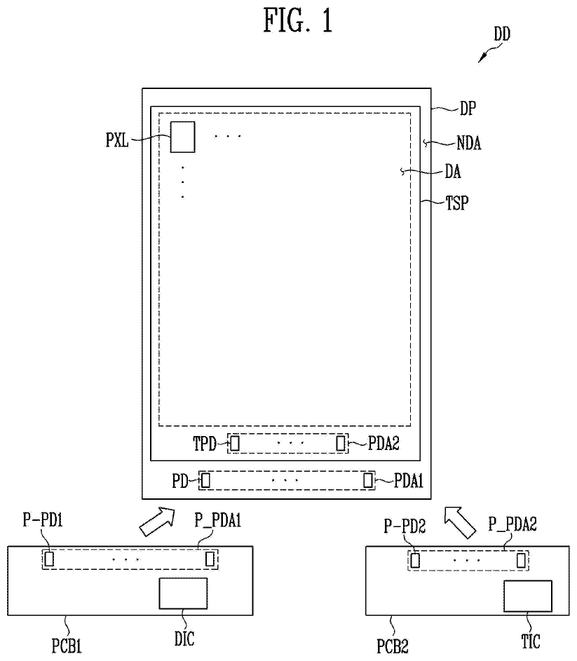

FIG. 1 is a diagram schematically illustrating a display device according to an embodiment of the present invention.

Referring to FIG. 1, the display device DD may include a display panel DP and a touch panel TSP. In an embodiment of the present invention, the display device DD may include a first circuit board PCB1 connected to the display panel DP and a second circuit board PCB2 connected to the touch panel TSP.

The display panel DP may display an image through a display surface. The display panel DP shown in FIG. 1 may have a flat display surface. The present invention is not limited thereto, and the display panel DP may have various types of display surfaces such as a curved display surface or a three-dimensional display surface.

In an embodiment of the present invention, the display panel DP may be a flexible display panel. For example, the display panel DP may be applied to a foldable display device, a bendable display device, a rollable display device, and the like. The disclosure is not limited thereto, and may be a rigid display device.

The display panel DP may include a display area DA and a non-display area NDA.

The display area DA is an area in which pixels PXL are provided to display an image. The pixel PXL may be disposed in the display area DA.

In an embodiment of the present invention, the pixel PXL may include an organic light emitting element including an organic emission layer. However, this is an example, and the pixel may include an inorganic light emitting element including an inorganic light emitting material.

The non-display area NDA may be positioned adjacent to the display area DA. The non-display area NDA may be provided on at least one side of the display area DA. For example, the non-display area NDA may surround a circumference (or, e.g., an edge) of the display area DA.

The non-display area NDA is an area in which the pixel PXL is not provided and is an area in which an image is not displayed. A portion of lines connected to the pixel PXL and a driver for driving the pixel PXL may be provided in the non-display area NDA.

In an embodiment of the present invention, the non-display area NDA may include a first pad area PDA1. Pads PD may be positioned in the first pad area PDA1. For example, an area in which the pads PD are disposed may be understood as the first pad area PDA1. In FIG. 1, the pads PD are arranged in a line, but the present invention is not limited thereto, and the pads PD may be disposed in various positions and in various shapes within the non-display area NDA.

The pads PD may be physically and/or electrically connected to first pads P-PD1 of the first circuit board PCB1.

The touch panel TSP may be disposed on the display panel DP. In an embodiment of the present invention, the touch panel TSP may be formed separately from the display panel DP, and may be attached on the display panel DP through a predetermined adhesive member. The touch panel TSP may include touch electrodes for sensing an input such as a touch. The touch electrodes may form a touch active area. For example, the touch active area may overlap the display area DA.

In addition, the touch panel TSP may further include lines extending from the touch electrodes. The lines may extend to a second pad area PDA2. In this case, the area of the touch panel TSP may be larger than that of the display area DA. The second pad area PDA2 may be included in a non-touch area adjacent to at least a portion of the touch active area.

In an embodiment of the present invention, as shown in FIG. 1, the touch panel TSP may have the area less than that of the display panel DP. However, this is an example, and the area of the touch panel TSP may be substantially the same as that of the display panel DP.

Touch pads TPD may be positioned in the second pad area PDA2. For example, an area in which the touch pads TPD are disposed may be understood as the second pad area PDA2. In FIG. 1, the touch pads TPD are arranged in a line, but the present inventive concept is not limited thereto, and the touch pads TPD may be disposed in various positions and in various shapes within the touch panel TSP.

For example, the pad PD to which signals for display are transmitted may be formed and disposed on the display panel DP, and the touch pad TPD to which signals for touch sensing are transmitted may be formed and disposed on the touch panel TSP.

The touch pads TPD may be physically and/or electrically connected to second pads P-PD2 of the second circuit board PCB2.

The first circuit board PCB1 may be electrically connected to the display panel DP. The first circuit board PCB1 may include a first pad area P_PDA1 in which the first pads P-PD1 are arranged. In an embodiment of the present invention, the first pads P-PD1 may be electrically connected to the pads PD of the display panel DP.

The first circuit board PCB1 may be a rigid circuit board or a flexible circuit board.

In an embodiment of the present invention, a display driver DIC that controls an operation of the display panel DP may be disposed on the first circuit board PCB1. In an embodiment of the present invention, the display driver DIC may include at least one integrated circuit (IC) and may be mounted on the first circuit board PCB1. However, this is an example, and a method of implementing the display driver DIC is not limited thereto. The display driver DIC may include a function of at least one of a timing controller, a data driver, and a scan driver.

A signal generated by the display driver DIC may be provided to the pixel PXL through the first pad P-PD1 and the pad PD of the display panel DP.

The second circuit board PCB2 may be electrically connected to the touch panel TSP. The second circuit board PCB2 may include a second pad area P_PDA2 in which the second pads P-PD2 are arranged. In an embodiment of the present invention, the second pads P-PD2 may be electrically connected to the touch pads TPD of the touch panel TSP.

The second circuit board PCB2 may be a rigid circuit board or a flexible circuit board.

In an embodiment of the present invention, a touch driver TIC that controls an operation of the touch panel TSP may be disposed on the second circuit board PCB2. In an embodiment of the present invention, the touch driver TIC may include at least one IC and may be mounted on the second circuit board PCB2. However, this is an example, and a method of implementing the touch driver TIC is not limited thereto.

The touch driver TIC and the touch panel TSP may transmit and receive an electrical signal through the second pad P-PD2 and the touch pad TPD of the touch panel TSP.

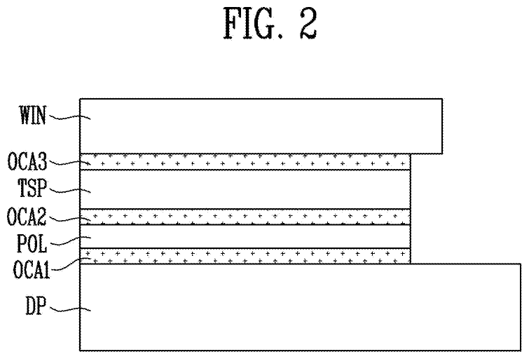

FIG. 2 is a schematic cross-sectional view illustrating an example of the display device of FIG. 1.

Referring to FIGS. 1 and 2, the display device DD may include the display panel DP and the touch panel TSP. The display device DD may further include a polarizer POL and a window WIN.

In an embodiment of the present invention, the polarizer POL may be attached and disposed on the display panel DP through a first optically clear adhesive OCA1. The polarizer POL may suppress reflection of external light in the display area DA to increase visibility of an image.

For example, the polarizer POL may be a film type or a liquid crystal coating type. The film type may include a stretched synthetic resin film, and the liquid crystal coating type may include liquid crystals arranged in a predetermined arrangement.

In an embodiment of the present invention, the touch panel TSP may be attached to the polarizer POL through a second optically clear adhesive OCA2. For example, the touch panel TSP may be provided in a film type. The touch panel TSP may include sensing electrodes for sensing a touch input.

The window WIN may be attached on the touch panel TSP through a third optically clear adhesive OCA3. In an embodiment of the present invention, the window WIN may include a glass substrate and/or a synthetic resin film.

In an embodiment of the present invention, the window WIN may further include a light blocking pattern. The light blocking pattern may define the non-display area NDA (for example, a bezel) of the display device DD. The light blocking pattern may include a colored organic layer and may be formed in a coating method.

In an embodiment of the present invention, the window WIN may further include a functional coating layer. For example, the functional coating layer may include an anti-fingerprint layer, an anti-reflection layer, a hard coating layer, and the like.

According to an embodiment of the present invention, the first to third optically clear adhesives OCA1, OCA2, and OCA3 may be provided in a film or resin type.

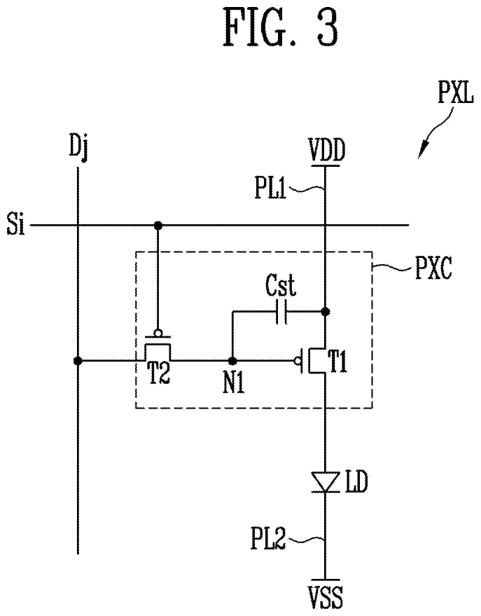

FIG. 3 is a circuit diagram illustrating an example of the pixel included in the display device of FIG. 1.

In FIG. 3, a pixel PXL positioned on an i-th horizontal line (or an i-th pixel row) and connected to a j-th data line Dj is shown for convenience of description (where i and j are natural numbers).

Referring to FIGS. 1 and 3, the display panel DP of the display device DD may include the pixel PXL. The pixel PXL may include a pixel circuit PXC and a light emitting element LD.

A first electrode (e.g., an anode electrode or a cathode electrode) of the light emitting element LD may be connected to the pixel circuit PXC, and a second electrode (e.g., a cathode electrode or an anode electrode) may be connected to a second power line PL2 providing second power VSS. The light emitting element LD may generate light of a predetermined luminance in response to an amount of a current supplied from a first transistor T1.

In an embodiment of the present invention, the light emitting element LD may be an organic light emitting diode including an organic emission layer. In an embodiment of the present invention, the light emitting element LD may be an inorganic light emitting element formed of an inorganic material. In an embodiment of the present invention, the light emitting element LD may be a light emitting element configured of a combination of an inorganic material and an organic material. In addition, the light emitting element LD may have a form in which a plurality of inorganic light emitting elements are connected in parallel and/or in series between the second power VSS and the pixel circuit PXC.

The pixel circuit PXC may include the first transistor T1, a second transistor T2, and a storage capacitor Cst. However, a structure of the pixel circuit PXC is not limited to the embodiment shown in FIG. 3.

The first transistor T1 (e.g., a driving transistor) may be connected between a first power line PL1 that transmits first power VDD and the light emitting element LD. A gate electrode of the first transistor T1 may be connected to a first node N1. The first transistor T1 controls an amount of a driving current supplied to the light emitting element LD in response to a voltage of the first node N1.

The second transistor T2 (e.g., a switching transistor) may be connected between a data line Dj and the first node N1. A gate electrode of the second transistor T2 may be connected to a scan line Si.

The second transistor T2 may be turned on in response to a scan signal supplied to the scan line Si, and a data signal may be transmitted to the first node N1 when the second transistor T2 is turned on. The data signal transmitted to the first node N1 may be charged in the storage capacitor Cst.

The storage capacitor Cst may be connected between the first power VDD and the first node N1. The storage capacitor Cst charges a voltage corresponding to the data signal supplied to the first node N1 and maintains the charged voltage until a data signal of a next frame is supplied.

A structure of the pixel circuit PXC may be variously changed and implemented. For example, the pixel circuit PXC may further include at least one transistor such as a transistor for compensating for a threshold voltage of the first transistor T1, a transistor for initializing the first node N1, and/or a transistor for controlling an emission time of the light emitting elements LD, or other circuit elements such as a boosting capacitor for boosting the voltage of the first node N1.

In addition, in FIG. 3, both of the first and second transistors T1 and T2 are P-type, but this is an example, and at least one of the first and second transistors T1 and T2 may be changed to an N-type transistor. In addition, a connection position of some components may be changed due to a change of a transistor type.

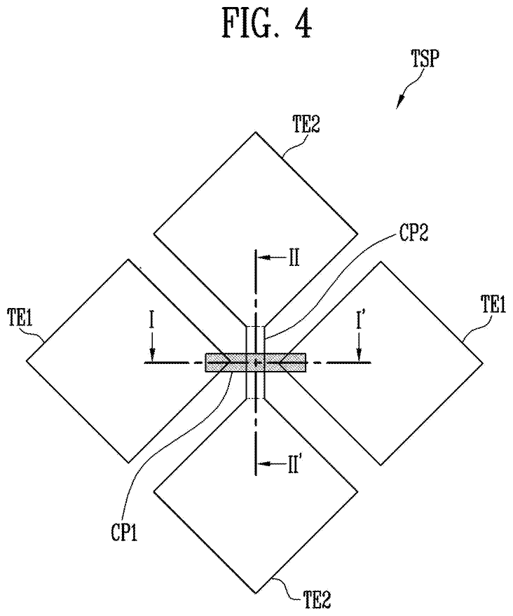

FIG. 4 is a schematic plan view illustrating an example of a portion of the touch panel included in the display device of FIG. 1.

Referring to FIGS. 1 and 4, the touch panel TSP (for example, a touch active area of the touch panel TSP) may include a first touch electrode TE1, a second touch electrode TE2, a first connection portion CP1, and a second connection portion CP2 in one crossing area.

FIG. 4 shows a portion of the touch active area of the touch panel TSP, and a pattern of FIG. 4 may be repeated in up, down, left, and right directions.

The first touch electrodes TE1 may be disposed to be spaced apart from each other. The first touch electrodes TE1 may be connected to each other by the first connection portion CP1. The first connection portion CP1 may connect the first touch electrodes TE1 adjacent to each other in a bridge shape through a contact hole. For example, the first connection portion CP1 may be disposed on a level different from that of the first touch electrodes TE1, and may be connected to the first touch electrodes TE1 through contact holes.

The second touch electrode TE2 and the second connection portion CP2 may be connected to each other on one plane. For example, the second touch electrode TE2 and the second connection portion CP2 may be integrally formed. The second touch electrode TE2 may be disposed to be spaced apart from the first touch electrode TE1.

In an embodiment of the present invention, the first touch electrode TE1, the second touch electrode TE2, the first connection portion CP1, and the second connection portion CP2 may include a transparent conductive material. For example, the first touch electrode TE1 and the second touch electrode TE2 may include a transparent conductive oxide, such as indium tin oxide (ITO), indium zinc oxide (IZO), zinc oxide (ZnO), or indium tin zinc oxide (ITZO).

In an embodiment of the present invention, the first touch electrode TE1, the second touch electrode TE2, the first connection portion CP1, and the second connection portion CP2 may include a conductive polymer such as PEDOT, a metal nanowire, graphene, or the like.

In an embodiment of the present invention, each of the first touch electrode TE1 and the second touch electrode TE2 may have a mesh shape to prevent each of the first touch electrode TE1 and the second touch electrode TE2 from being viewed by a user.

A touch sensor including the touch panel TSP may sense a touch by a capacitance change between the first touch electrode TE1 and the second touch electrode TE2.

A planar shape of the touch electrodes TE1 and TE2 of FIG. 4 is an example and is not limited thereto. The planar shape and an arrangement direction of the touch electrodes TE1 and TE2 may be modified in various forms. In addition, a position and a planar shape of the connection portions CP1 and CP2 may be variously modified.

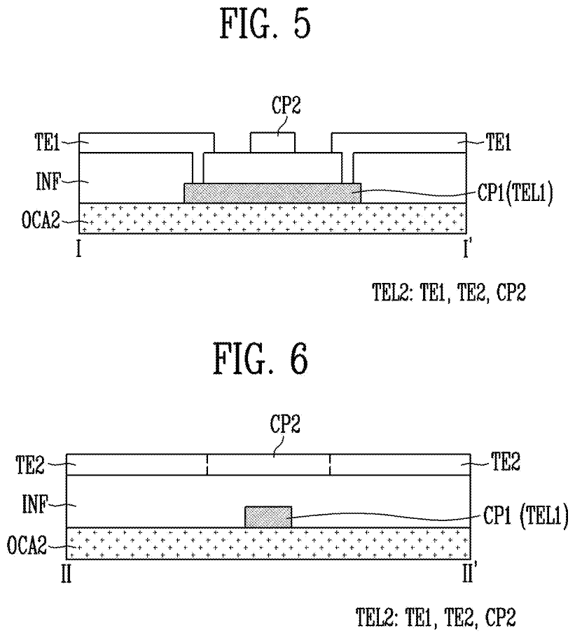

FIG. 5 is a schematic cross-sectional view illustrating an example of the touch panel of FIG. 4 taken along a line I-I′, and FIG. 6 is a schematic cross-sectional view of an example of the touch panel of FIG. 4 taken along a line II-II′.

Referring to FIGS. 2, 4, 5, and 6, the touch panel TSP may include two touch electrode layers TEL1 and TEL2 and an insulating film INF therebetween.

In an embodiment of the present invention, a first touch electrode layer TEL1 may be disposed on the second optically clear adhesive OCA2. The first touch electrode layer TEL1 may include the first connection portion CP1.

The insulating film INF may cover the first touch electrode layer TEL1 and may be disposed on the second optically clear adhesive OCA2. The insulating film INF may have a single layer or multiple layer structure. The insulating film INF may include an inorganic material, an organic material, or a composite material.

A contact hole partially exposing the first touch electrode layer TEL1 may be provided in the insulating film INF.

The second touch electrode layer TEL2 may be disposed on the insulating film INF. A portion of the second touch electrode layer TEL2 may be connected to the first touch electrode layer TEL1 through a contact hole. The second touch electrode layer TEL2 connected to the first touch electrode layer TEL1 may be a first touch electrode TE1.

A portion of the second touch electrode layer TEL2 may cross and overlap the first touch electrode layer TEL1. The second touch electrode layer TEL2 that crosses and overlaps the first touch electrode layer TEL1 may be the second connection portion CP2. In addition, the second touch electrode layer TEL2 may include a second touch electrode TE2 and the second connection portion CP2 that are integrally formed.

However, this is an example, and the first touch electrode layer TEL1 may include the first touch electrode TE1, the second touch electrode TE2, and the second connection portion CP2, and the second touch electrode layer TEL2 may include the first connection portion CP1.

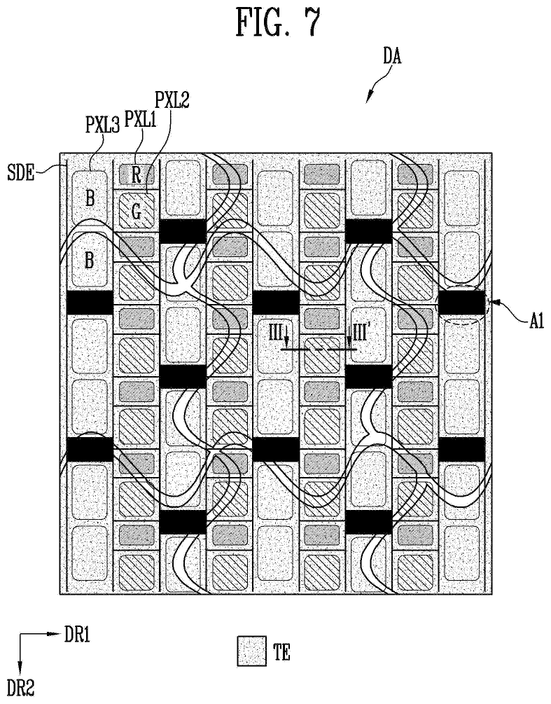

FIG. 7 is a schematic plan view illustrating an example of the display area of the display device of FIG. 1.

Referring to FIGS. 1, 2, 3, and 7, in the display area DA of the display device DD, pixels PXL1, PXL2, and PXL3, a shielding electrode SDE, and a touch electrode TE may be disposed.

In FIG. 7, for convenience of description and understanding, the emission area of the pixel is described as each of the pixels PXL1, PXL2, and PXL3.

The pixels PXL1, PXL2, and PXL3 may include a first pixel PXL1, a second pixel PXL2, and a third pixel PXL3. The first pixel PXL1 may emit a first color (for example, red). The second pixel PXL2 may emit a second color (for example, green), and the third pixel PXL3 may emit a third color (for example, blue).

In an embodiment of the present invention, as shown in FIG. 7, the third pixel PXL3 may be arranged in a second direction DR2, and the first pixel PXL1 and the second pixel PXL2 may be alternately arranged in the second direction DR2. In addition, the first pixel PXL1 and the second pixel PXL2 may be alternately arranged with the third pixel PXL3 in a first direction DR1 that crosses the second direction DR2.

The first pixel PXL1, the second pixel PXL2, and the third pixel PXL3 may be divided by a pixel defining layer. In other words, the pixel defining layer may define emission areas of each of the first pixel PXL1, the second pixel PXL2, and the third pixel PXL3. In FIG. 7, all areas other than portions partitioned by the first pixel PXL1, the second pixel PXL2, and the third pixel PXL3 may be a portion corresponding to the pixel defining layer as the non-emission areas.

In an embodiment of the present invention, the emission area of each of the first pixel PXL1, the second pixel PXL2, and the third pixel PXL3 may have a structure in which a first electrode (for example, an anode electrode), a light emitting layer, and a second electrode (for example, a cathode electrode) are stacked.

The touch electrode TE of the touch panel TSP may be disposed to overlap the display area DA. For example, as shown in FIG. 7, at least a portion of the touch electrodes TE may be disposed to be spaced apart from each other by a wave shape of boundary. For convenience of understanding, in FIG. 7, the touch electrodes TE are disposed to be spaced apart from each other based on the wave shape boundary, and a disposition shape of the touch electrodes TE on a plane is not limited thereto. For example, the touch electrodes TE may be disposed as in the planar shape shown in FIG. 4.

In an embodiment of the present invention, one touch electrode TE may overlap the plurality of pixels PXL1, PXL2, and PXL3. For example, the touch electrode TE may overlap the emission areas and the non-emission areas of the pixels PXL1, PXL2, and PXL3. In other words, the planar area of the touch electrode TE may be greater than the planar area of each of the pixels PXL1, PXL2, and PXL3.

When the display device DD is driven, a capacitance may be formed between the touch electrode TE of the touch panel TSP and the second electrode (for example, the cathode electrode), which is included in the light emitting elements of the pixels PXL1, PXL2 and PXL3 of the display panel DP. Such a capacitance may affect driving of another side when each of the touch panel TSP and the display panel DP is driven. For example, the capacitance (hereinafter, referred to as a noise capacitance) between the touch electrode TE and the second electrode may act as noise, and thus, touch sensing performance may be reduced.

To prevent the noise, a distance between the second electrode and the touch electrode TE may be increased. For example, when an external touch panel TSP is attached on the display panel DP using an optically clear adhesive material, the distance between the second electrode and the touch electrode TE may be increased, and thus the noise capacitance may be reduced. However, when the display device DD is enlarged, even though the distance between the display panel DP and the touch panel TSP increases, an influence of noise due to the noise capacitance may be generated.

The display device DD according to an embodiment of the present invention may include a shielding electrode SDE for removing or minimizing an influence of the noise capacitance. In an embodiment of the present invention, the display panel DP may include a shielding layer including the shielding electrode SDE.

The shielding electrode SDE may be disposed on a thin film encapsulation layer of the display panel. The shield electrode SDE may overlap the non-emission area. For example, the shielding electrode SDE may avoid the emission area (for example, the pixels PXL1, PXL2, and PXL3) and overlap the pixel defining layer. For example, the shielding electrode SDE may be disposed so as not to reduce visibility of an image.

In an embodiment of the present invention, the shielding electrode SDE may extend to the non-display area NDA and may be electrically connected to some of the pads PD of the display panel DP. Predetermined DC power may be supplied to the pad PD to which the shielding electrode SDE is connected. For example, a voltage of the first power VDD or the second power VSS may be supplied to the shielding electrode SDE. However, this is an example, and the shielding electrode SDE may be connected to a ground.

As described above, since the shielding electrode SDE to which the predetermined DC power is provided is disposed between the second electrode of the display panel DP and the touch electrode TE of the touch panel TSP, the noise capacitance may be reduced or minimized, Therefore, the touch sensing characteristic (e.g., the sensing accuracy and the sensitivity) may be improved.

In an embodiment of the present invention, the shielding electrode SDE may include an opaque metal. For example, the shielding electrode SDE may be formed of at least one of metals such as gold (Au), silver (Ag), aluminum (Al), molybdenum (Mo), chromium (Cr), titanium (Ti), nickel (Ni), neodymium (Nd), and copper (Cu), or an alloy of metals.

In an embodiment of the present invention, a width of the shielding electrode SDE may be narrower than a width of the pixel defining layer overlapping therewith in the display area DA. Therefore, the shielding electrode SDE does not overlap the emission area. The width of the shielding electrode SDE may be non-uniform.

For example, one portion of the shielding electrode SDE overlapping one area (indicated by A1) having a relatively wide distance between the third pixels PXL3 may have a width wider (and the area larger) than that of other portions. However, this is an example, and the width of the shielding electrode SDE may be freely modified within a range that does not exceed the width of the corresponding pixel defining layer.

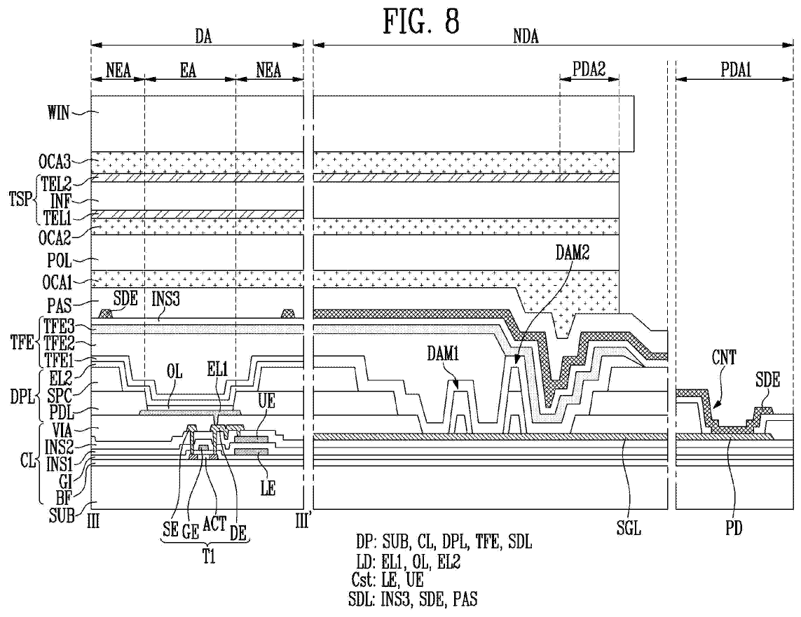

FIG. 8 is a schematic cross-sectional view illustrating an example of the display area and the non-display area of the display device of FIG. 1.

FIG. 8 shows a portion along a line III-III′ of the display area DA of FIG, 7 and the non-display area NDA.

Referring to FIGS. 1, 2, 3, 4, 7, and 8, the display device DD may include the display panel DP, the touch panel TSP, the polarizer POL, and the window WIN.

The display panel DP may include a substrate SUB, a circuit element layer CL, a display element layer DPL, a thin film encapsulation layer TFE, and a shielding layer SDL.

The substrate SUB may include the display area DA and the non-display area NDA. The display area DA may include the emission area EA and the non-emission area NEA. The non-display area NDA may include the first pad area PDA1 in which the pad PD is disposed.

The substrate SUB may include a synthetic resin film. A synthetic resin layer may be a polyimide-based resin layer, and a material thereof is not particularly limited. In addition, the substrate SUB may include, for example, a glass substrate, a metal substrate, an organic/inorganic composite substrate, or the like.

The circuit element layer CL may include at least one insulating layer and a circuit element. For example, the circuit element layer CL may include a buffer layer BF, a gate insulating layer GI, insulating layers INS1 and INS2, and an active pattern ACT and various conductive layers for configuring a circuit element.

The buffer layer BF may prevent an impurity from diffusing into the circuit element including the first transistor T1. The buffer layer BF may be an inorganic insulating layer formed of an inorganic material.

An active pattern ACT may be disposed on the buffer layer BF. The active pattern ACT is formed of a semiconductor material. Each of the active patterns ACT may include a source area, a drain area, and a channel area provided between the source area and the drain area. The active pattern ACT may be a semiconductor pattern formed of polysilicon, amorphous silicon, oxide semiconductor, or the like.

A gate insulating layer GI may be provided on the active pattern ACT. The gate insulating layer GI may be an inorganic insulating layer formed of an inorganic material.

A gate electrode GE and a capacitor lower electrode LE may be provided on the gate insulating layer GI. The gate electrode GE is formed to cover an area corresponding to the channel area of the active pattern ACT.

The gate electrode GE and the capacitor lower electrode LE may be formed of a metal. For example, the gate electrode GE may be formed of at least one of metals such as gold (Au), silver (Ag), aluminum (Al), molybdenum (Mo), chromium (Cr), titanium (Ti), nickel (Ni), neodymium (Nd), and copper (Cu), or an alloy of metals. In addition, the gate electrode GE may be formed as a single layer or multiple layers in which two or more materials of metals and alloys are stacked.

A first insulating layer INS1 may be provided on the gate electrode GE and the capacitor lower electrode LE. The first insulating layer INS1 may be an inorganic insulating layer formed of an inorganic material. For example, as the inorganic material, polysiloxane, silicon nitride, silicon oxide, silicon oxynitride, or the like may be used.

A capacitor upper electrode UE may be provided on the first insulating layer INS1. The capacitor upper electrode UE may include a metal.

The capacitor lower electrode LE and the capacitor upper electrode UE may constitute the capacitor Cst with the first insulating layer INS1 interposed therebetween.

A second insulating layer INS2 may be provided on the capacitor upper electrode UE. The second insulating layer INS2 may be an inorganic insulating layer formed of an inorganic material. For example, as the inorganic material, polysiloxane, silicon nitride, silicon oxide, silicon oxynitride, or the like may be used.

A source electrode SE and a drain electrode DE may be provided on the second insulating layer INS2. The source electrode SE and the drain electrode DE respectively contacts the source area and the drain area of the active pattern ACT through a contact hole formed in the second insulating layer INS2, the first insulating layer INS1, and the gate insulating layer GI.

The source electrode SE and the drain electrode DE may be formed of a metal.

In an embodiment of the present invention, at least one of the data line Dj, the scan line Si, and the power lines PL1 and PL2 may be provided on the same layer and formed of the same material as the source electrode SE and the drain electrode DE. These lines may extend to the non-display area NDA as a signal line SGL. In addition, the signal line SGL may be exposed in the first pad area PDA1 to function as the pad PD. The pad PD may be physically/electrically connected to the first circuit board PCB1.

A via layer VIA may be disposed on the source electrode SE, the drain electrode DE, and the signal line SGL. The via layer VIA may be an organic insulating layer formed of an organic material. For example, as the organic material, an organic insulating material such as a polyacryl-based compound, a polyimide-based compound, a fluorine-based carbon compound such as Teflon, or a benzocyclobutene compound may be used.

In an embodiment of the present invention, the via layer VIA may also be disposed in the first pad area PDA1.

The display element layer DPL may include the light emitting element LD and a pixel defining layer PDL.

The light emitting element LD may include a first electrode EL1, a light emitting layer OL, and a second electrode EL2.

The first electrode EL1 may be disposed on the via layer VIA. The first electrode EL1 may be connected to the drain electrode DE through a contact hole passing through the via layer VIA. The first electrode EL1 may be used as one of the anode or the cathode according to an embodiment of the present invention.

The first electrode EL1 may be formed of a metal layer such as Ag, Mg, Al, Pt, Pd, Au, Ni, Nd, Ir, Cr, or an alloy thereof, indium tin oxide (ITO) or indium zinc oxide (IZO), zinc oxide (ZnO), indium tin zinc oxide (ITZO), and/or the like.

The pixel defining layer PDL that partitions the emission area EA to correspond to each pixel PXL may be provided on the via layer VIA on which the first electrode EL1 is formed. The pixel defining layer PDL may be an organic insulating layer. In addition, the pixel defining layer may also be disposed in a portion of the non-display area NDA.

The pixel defining layer PDL may expose an upper surface of the first electrode EL1 and may protrude from the substrate SUB along a periphery of the emission area EA.

In an embodiment of the present invention, a spacer SPC may be further disposed on the pixel defining layer PDL. The spacer SPC may be disposed to secure a step difference between the emission area EA and the non-emission area NEA. The spacer SPC may be an organic insulating layer including an organic material.

The light emitting layer OL may be provided in the emission area EA and may be surrounded by the pixel defining layer PDL. The light emitting layer OL may be provided as a single layer, but may be provided as multiple layers including various functional layers. When the light emitting layer OL is provided in the multiple layers, the light emitting layer OL may have a structure in which a hole injection layer (HIL), a hole transport layer (HTL), an emission layer (EML), an electron transport layer (ETL), an electron injection layer (EIL), and the like are stacked in a single or complex structure.

The second electrode EL2 is provided on the light emitting layer OL. The second electrode EL2 may be provided for each pixel PXL or may be provided to cover most of the display area DA.

The second electrode EL2 may be used as one of the anode or the cathode according to an embodiment of the present invention. When the first electrode EL1 is the anode, the second electrode EL2 may be used as the cathode, and when the first electrode EL1 is the cathode, the second electrode EL2 may be used as the anode.

The second electrode EL2 may be formed of a metal layer such as Ag, Mg, Al, Pt, Pd, Au, and Ni, Nd, Ir, or Cr, and/or a transparent conductive layer such as indium tin oxide (ITO), indium zinc oxide (IZO), zinc oxide (ZnO), or indium tin zinc oxide (ITZO). In an embodiment of the present invention, the second electrode EL2 may be formed of multiple layers of double or more layers including a thin metal layer, and for example, the second electrode EL2 may be formed of triple layers of ITO/Ag/ITO.

The thin film encapsulation layer TFE may be provided on the second electrode EL2. In an embodiment of the present invention, the thin film encapsulation layer TFE may include a first encapsulation layer TFE1, a second encapsulation layer TFE2, and a third encapsulation layer TFE3 stacked on the display element layer DPL. The first encapsulation layer TFE1, the second encapsulation layer TFE2, and the third encapsulation layer TFE3 may be formed of an organic material and/or an inorganic material. The third encapsulation layer TFE3 positioned on the uppermost layer may be formed of an inorganic material. In an embodiment of the present invention, the first encapsulation layer TFE1 may be formed of an inorganic material. The second encapsulation layer TFE2 may be formed of an organic material, and the third encapsulation layer TFE3 may be formed of an inorganic material. In a case of the inorganic material, penetration of moisture or oxygen is less than that of the organic material, but elasticity or flexibility of the inorganic material is less than that of the organic material, and thus the inorganic material is vulnerable to a crack. Accordingly, propagation of the crack may be prevented by forming the second encapsulation layer TFE2 using the organic material. Here, a layer formed of the organic material, that is, the second encapsulation layer TFE2 may be completely covered by the third encapsulation layer TFE3 so that an end portion of the second encapsulation layer TFE2 is not exposed to an outside. For example, as the organic material, an organic insulating material such as a polyacryl-based compound, a polyimide-based compound, a fluorine-based carbon compound such as Teflon, or a benzocyclobutene compound may be used, and as the inorganic material, polysiloxane, silicon nitride, silicon oxide, silicon oxynitride, and the like may be used.

In an embodiment of the present invention, the thin film encapsulation layer TFE may cover the display area DA and may extend beyond the display area DA (that is, a portion of the non-display area NDA).

In an embodiment of the present invention, the via layer VIA and/or the pixel defining layer PDL formed of an organic material might not successively extend to the non-display area NDA, and may have an opening in which a portion thereof is removed along a periphery of the display area DA.

In an embodiment of the present invention, a first dam portion DAM1 and a second dam portion DAM2 may be further included in the non-display area NDA. The first dam portion DAM1 and the second dam portion DAM2 may at least partially surround the display area DA.

The first dam portion DAM1 may have a double layer structure. For example, a lower structure of the first dam portion DAM1 may be formed simultaneously with the via layer VIA, and an upper structure may be formed simultaneously with the pixel defining layer PDL.

The second dam portion DAM2 may have a triple layer structure and may be formed to be higher than the first dam portion DAM1. For example, the second dam portion DAM2 may be formed through processes of the via layer VIA, the pixel defining layer PDL, and the spacer SPC.

The first dam portion DAM1 and the second dam portion DAM2 may prevent a liquid organic material from overflowing toward the first pad area PDA1 in a process of forming the second encapsulation layer TFE2.

However, this is an example, and according to an embodiment of the present invention, at least one of the first dam portion DAM1 and the second dam portion DAM2 may be removed, or additional dam portions may be disposed.

The shielding layer SDL may be disposed on the thin film encapsulation layer TFE. In an embodiment of the present invention, the shielding layer SDL may include a third insulating layer INS3, the shielding electrode SDE, and a passivation layer PAS.

The third insulating layer INS3 may be disposed on the thin film encapsulation layer TFE. For example, the third insulating layer INS3 may be formed on the entire surface of the display area DA and the non-display area NDA. A portion of the third insulating layer INS3 may be removed to expose the pad PD. The third insulating layer INS3 may be an inorganic insulating layer or an organic insulating layer.

The shielding electrode SDE may be disposed on the third insulating layer INS3, The shielding electrode SDE may be disposed in the display area DA and the non-display area NDA.

In an embodiment of the present invention, the shielding electrode SDE may overlap the pixel defining layer PDL in the display area DA. In addition, a width of the shielding electrode SDE may be less than a width of the pixel defining layer PDL overlapping the shielding electrode SDE. In the display area DA, the shielding electrode SDE may suppress formation of a capacitance between the second electrode EL2 and the touch panel TSP.

The shielding electrode SDE may extend to the non-display area NDA. In an embodiment of the present invention, the shielding electrode SDE may extend to the first pad area PDA1 and may be physically and electrically connected to the pad PD through a contact hole CNT exposing the pad PD. In addition, the signal line SGL connected to the pad PD may be the first power line PL1 providing the voltage of the first power VDD or may be the second power line PL2 transmitting the voltage of the second power VSS. Therefore, a constant voltage may be supplied to the shielding electrode SDE.

The passivation layer PAS may cover the shielding electrode SDE and may be disposed on the third insulating layer INS3. For example, the passivation layer PAS may be provided in the entire display area DA and a portion of the non-display area NDA. For example, the passivation layer PAS is not provided in the first pad area PDA1. The passivation layer PAS may be an inorganic insulating layer.

The shielding layer SDL may be formed during a manufacturing process of the display panel DP.

In an embodiment of the present invention, the first optically clear adhesive OCA1 may be provided on the shielding layer SDL, and the polarizer POL may be attached on the display panel DP by the first optically clear adhesive OCA1. For example, the polarizer POL may be attached to the passivation layer PAS by the first optically clear adhesive OCA1.

The second optically clear adhesive OCA2 may be provided on the polarizer POL, and the touch panel TSP may be attached on the polarizer POL by the second optically clear adhesive OCA2.

The polarizer POL and the touch panel TSP may overlap the display area DA and the non-display area NDA. The polarizer POL and the touch panel TSP may overlap the entire display area DA and at least a portion of the non-display area NDA.

The touch panel TSP may include the first touch electrode layer TEL1, the insulating film INF, and the second touch electrode layer TEL2. According to an embodiment of the present invention, the first touch electrode layer TEL1 and the second touch electrode layer TEL2 may form the touch electrodes as described with reference to FIG. 4 in correspondence with the display area DA.

In an embodiment of the present invention, the touch panel TSP may include the touch pads TPD that overlap a portion of the non-display area NDA and are connected to the first touch electrode layer TEL1 or the second touch electrode layer TEL2. An area in which the touch pads TPDs are arranged may be defined as a second pad area PDA2. The above-described second circuit board PCB2 may be electrically/physically connected to the second pad area PDA2.

A third optically clear adhesive OCA3 may be provided on the touch panel TSP, and the window WIN may be attached on the touch panel TSP by the third optically clear adhesive OCA3.

As described above, the display device DD according to an embodiment of the present invention may include the shielding electrode SDE disposed to overlap the pixel defining layer PDL on the thin film encapsulation layer TFE. The shielding electrode SDE may be electrically connected to some pads PD of the display panel DP to receive the first power VDD or the second power VSS. Therefore, formation of a capacitance between the display element layer DPL and the touch electrode TE may be suppressed or minimized, and the touch sensing characteristic (e.g., the sensing accuracy and the sensitivity) may be improved without decreased or blocked visibility and an excessive increase of a manufacturing cost.

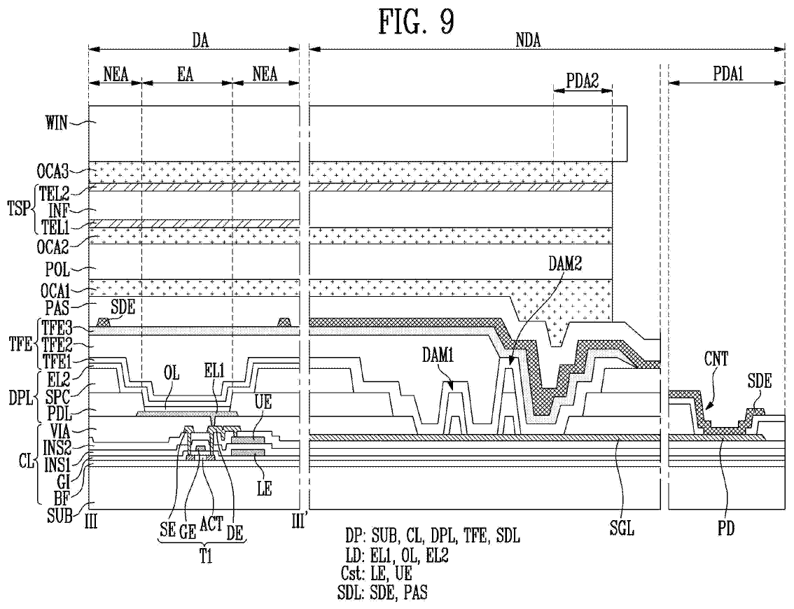

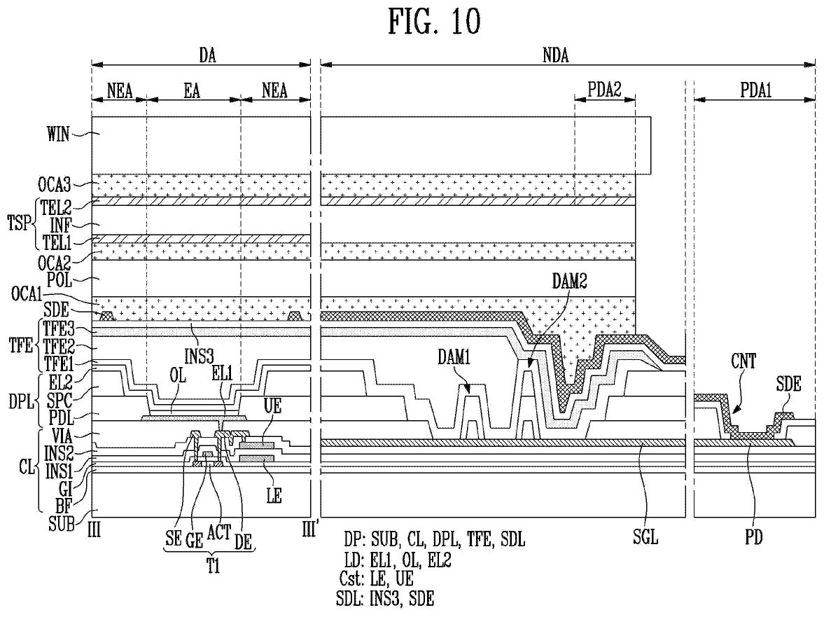

FIG. 9 is a schematic cross-sectional view illustrating an example of the display area and the non-display area of the display device of FIG. 1, and FIG. 10 is a schematic cross-sectional view illustrating an example of the display area and the non-display area of the display device of FIG. 1.

In FIGS. 9 and 10, the same reference numerals are used for the components described in FIG. 8, and an overlapping description of these components may be omitted or briefly discussed. The display device of FIGS. 9 and 10 has a configuration substantially identical or similar to that of the display device of FIG. 8, except for a configuration of the shielding layer SDL.

Referring to FIGS. 9 and 10, the display device DD may include the display panel DP, the touch panel TSP, the polarizer POL, and the window WIN. A partial configuration of an insulating layer in the shielding layer SDL of the display panel DP may be omitted.

In an embodiment of the present invention, as shown in FIG. 9, the shielding layer SDL may include the shielding electrode SDE and the passivation layer PAS. That is, the third insulating layer INS3 may be omitted. The shielding electrode SDE may be directly patterned on the encapsulation layer TEF.

In an embodiment of the present invention, as shown in FIG. 10, the shielding layer SDL may include the third insulating layer INS3 and the shielding electrode SDE. That is, the passivation layer PAS may be omitted. Therefore, the shielding electrode SDE may be directly patterned on the encapsulation layer TEF. The first optically clear adhesive OCA1 may be directly provided on the shielding electrode SDE and the third insulating layer INS3.

The display device according to the embodiment of FIGS. 9 and 10 may reduce a manufacturing cost because a deposition process of forming the display panel DP is reduced compared to the display device of FIG. 8.

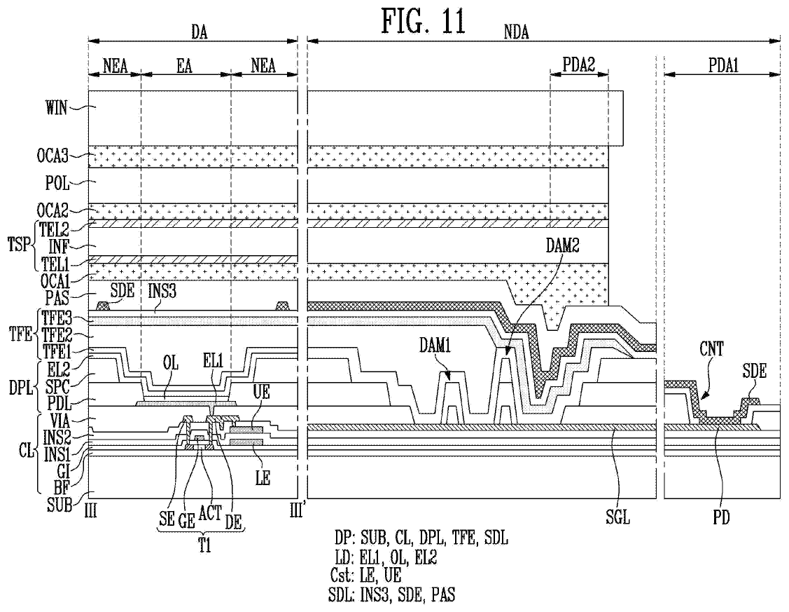

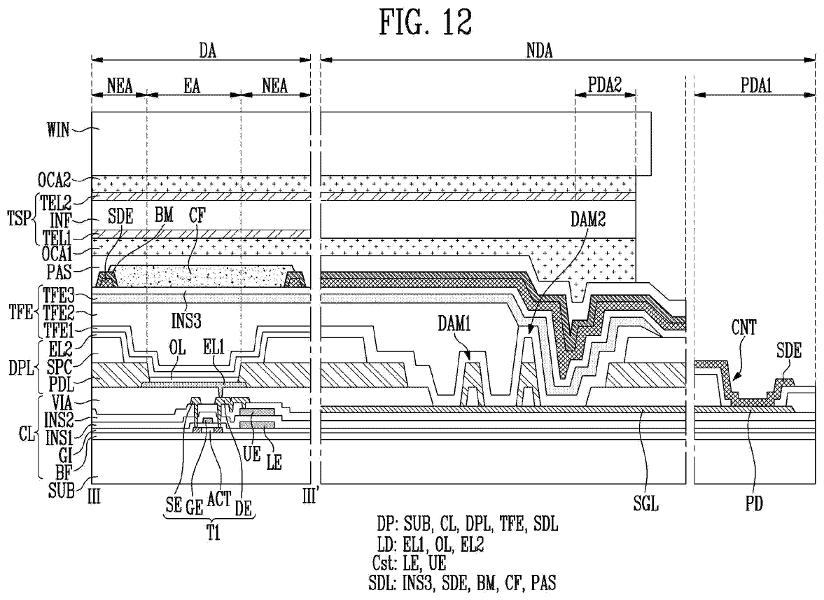

FIG. 11 is a schematic cross-sectional view illustrating an example of the display area and the non-display area of the display device of FIG. 1.

In FIG. 11, the same reference numerals are used for the components described with reference to FIG. 8, and an overlapping description of these components may be omitted or briefly discussed. The display device of FIG. 11 has a configuration substantially identical or similar to that of the display device of FIG. 8 except for a position of the polarizer POL and the touch panel TSP.

Referring to FIG. 11, the display device DD may include the display panel DP, the touch panel TSP, the polarizer POL, and the window WIN.

In an embodiment of the present invention, the touch panel TSP may be disposed on the display panel DP, and the polarizer POL may be disposed on the touch panel TSP. In this case, an external light reflection effect may be improved, and this case may provide increased visibility compared to the embodiment of FIG. 8.

In a case of the embodiment of FIG. 8, compared to the embodiment of FIG. 11, a distance between the touch panel TSP and the display panel DP is greater, and thus, the display device of FIG. 8 may have increased touch sensing performance than the display device of FIG. 11.

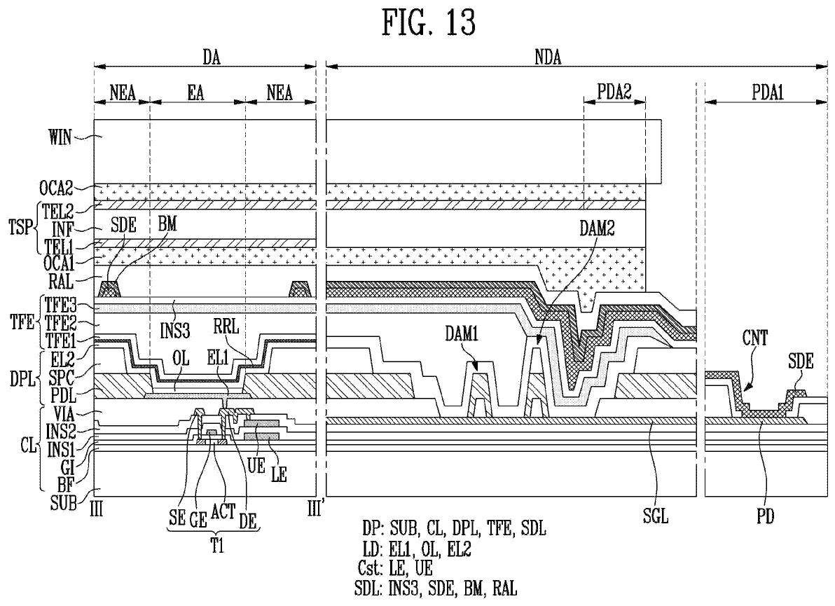

FIG. 12 is a schematic cross-sectional view illustrating an example of the display area and the non-display area of the display device of FIG. 1.

In FIG. 12, the same reference numerals are used for the components described with reference to FIG. 8, and an overlapping description of these components may be omitted or briefly discussed. The display device of FIG. 12 may have a structure in which the polarizer POL is removed.

Referring to FIG. 12, the display device DD may include the display panel DP, the touch panel TSP, and the window WIN.

The display device DD may include a structure of the shielding layer SDL to replace a function of the polarizer POL shown in FIG. 8. In an embodiment of the present invention, the shielding layer SDL may include the third insulating layer INS3, the shielding electrode SDE, a black matrix BM, a color filter CF, and the passivation layer PAS.

The black matrix BM may cover at least a portion of the shielding electrode SDE. The black matrix BM may absorb or block light introduced from an outside. The black matrix BM may include an organic light blocking material. For example, the organic light blocking material may include at least one of carbon black (CB) and/or titanium black (TiBK), but the present invention is not limited thereto.

Accordingly, the black matrix BM may prevent or minimize unintentional light reflection or the like from the shielding electrode SDE. Therefore, a visibility defect due to a disposition of the shielding electrode SDE may be prevented.

The color filter CF may be disposed on the third insulating layer INS3. The color filter CF may overlap the emission area EA. The color filter CF may overlap at least a portion of the shielding electrode SDE and may contact the black matrix BM.

The color filter CF may have a color corresponding to the pixel PXL overlapping the color filter CF. For example, a color filter CF overlapping a red pixel may be a red color filter. For example, a color filter CF overlapping a green pixel may be a green color filter, and a color filter CF overlapping a blue pixel may be a blue color filter.

As described above, since the color filter CF is disposed in the shielding layer SDL to replace the polarizer POL, a thickness increase of the display device DD due to insertion of the shielding layer SDL may be minimized or the display device DD may have a reduced thickness.

The passivation layer PAS may cover the black matrix BM and the color filter CF.

In an embodiment of the present invention, the pixel defining layer PDL may have a black color. Accordingly, a black visual sense may be improved.

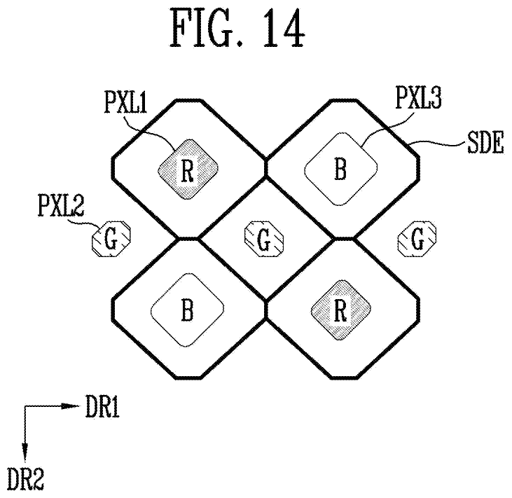

FIG. 13 is a schematic cross-sectional view illustrating an example of the display area and the non-display area of the display device of FIG. 1.

Referring to FIG. 13, the display device DD may include the display panel DP, the touch panel TSP, and the window WIN.

The display device DD may include a structure of the shielding layer SDL and the light emitting element layer DPL to replace the function of the polarizer POL shown in FIG. 8.

In an embodiment of the present invention, the light emitting element layer DPL may further include a low reflection layer RRL disposed on the second electrode EL2. For example, the low reflection layer RRL may include an inorganic material of which a reflectance is low, and may include a metal or a metal oxide.

The low reflection layer RRL may include at least one of bismuth (Bi) and ytterbium (Yb). For example, the low reflection layer RRL may be formed by depositing bismuth (Bi) or may be formed by co-depositing bismuth (Bi) and ytterbium (Yb). Bismuth (Bi) and ytterbium (Yb) may be metals that may be deposited at a temperature at which a configuration of the light emitting layer OL or the like disposed under the low reflection layer RRL is not damaged.

The low reflection layer RRL may have a refractive index of about 1.4 or more and about 3.0 or less. The low reflection layer RRL may have an absorption coefficient (k) of 1.5 or less. For example, the low reflection layer RRL may have an absorption coefficient greater than about 0.5 and less than or equal to about 1.5. The low reflective layer RRL satisfying a predetermined refractive index range and absorption coefficient range may decrease a reflectance of light.

The low reflection layer RRL may decrease an external light reflectance by inducing destructive interference between light incident inside the display device DD and light reflected from a metal (for example, the second electrode EL2) disposed under the low reflection layer RRL. Accordingly, display quality and light efficiency of the display device DD including the low reflection layer RRL may be increased.

In an embodiment of the present invention, the shielding layer SDL may include the third insulating layer INS3, the shielding electrode SDE, the black matrix BM, and a reflection adjusting layer RAL. For example, the reflection adjusting layer RAL may replace the passivation layer PAS of FIG. 8.

In an embodiment of the present invention, the reflection adjusting layer RAL may include a dye or a pigment that absorbs light of a preset wavelength area. The reflection adjusting layer RAL may be disposed on the third insulating layer INS3 and may cover at least a portion of the black matrix BM and the shielding electrode SDE.

In an embodiment of the present invention, the reflection adjusting layer RAL may absorb light of a wavelength area of about 490 nm or more and about 500 nm or less or a wavelength area of about 500 nm or more and about 600 nm or less.

As described above, since the reflection adjusting layer RAL and the low reflection layer RRL may replace the function of the existing polarizer POL of FIG. 8, the polarizer may be removed. Therefore, a thickness increase of the display device DD due to an insertion of the shielding layer SDL may be minimized or the display device DD may have a reduced thickness because the polarizer may be removed.

In an embodiment of the present invention, the pixel defining layer PDL may have a black color. Accordingly, a black visual sense may be improved.

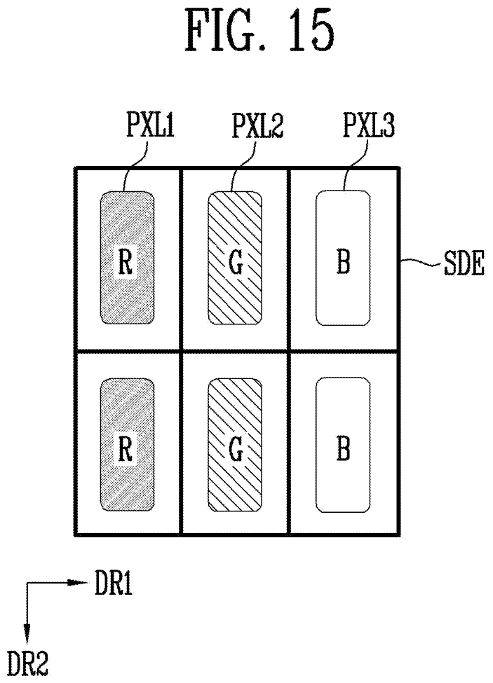

FIG. 14 is a schematic plan view illustrating an example of the pixels and the shielding electrode included in the display device of FIG. 1, and FIG. 15 is a schematic plan view illustrating an example of the pixels and the shielding electrode included in the display device of FIG. 1.

Referring to FIGS. 1, 2, 8, 14, and 15, in the display area DA, the shielding electrode SDE may avoid the emission area and may overlap the non-emission area (that is, the pixel defining layer PDL). For example, the shielding electrode SDE might not overlap the emission area.

The pixels PXL1, PXL2, and PXL3 may have various arrangement shapes, planar shapes, and sizes.

In an embodiment of the present invention, as shown in FIG. 14, the first pixel PXL1 and the third pixel PXL3 may be alternately arranged in the first direction DR1 in a first row. The second pixel PXL2 may be arranged in the first direction DR1 in a second row, and the third pixel PXL3 and the first pixel PXL1 may be alternately arranged in the first direction DR1 in a third row. The second pixel PXL2 may be arranged in the first direction DR1 in a fourth row. An arrangement rule of the pixels PXL1, PXL2, and PXL3 described above may be repeated.

In an embodiment of the present invention, as shown in FIG. 15, an arrangement of the first pixel PXL1, the second pixel PXL2, and the third pixel PXL3 may be repeated in each row.

The shielding electrode SDE may be disposed to overlap the non-emission area (that is, the pixel defining layer) that divides the pixels PXL1, PXL2, and PXL3.

While the present invention has been particularly shown and described with reference to embodiments thereof, it will be apparent those of ordinary skill in the art that various changes in form and detail may be made thereto without departing from spirit and scope of the present invention.

What is claimed is:

1. A display device comprising:
a display panel including a light emitting element layer including a pixel defining layer dividing a display area into an emission area and a non-emission area, a thin film encapsulation layer disposed on the light emitting element layer, and a shielding layer including a shielding electrode disposed on the thin film encapsulation layer that is disposed on a substrate including the display area and a non-display area; and
a touch panel attached to the display panel through a first optically clear adhesive and including touch electrodes,
wherein the light emitting element layer includes a light emitting layer corresponding to the emission area, and
the shielding electrode overlaps the non-emission area.

2. The display device according to claim 1, wherein the shielding layer further includes a black matrix covering at least a portion of the shielding electrode and overlapping the non-emission area.

3. The display device according to claim 2, wherein the shielding layer further includes a color filter overlapping at least a portion of the shielding electrode and the emission area and disposed on the black matrix.

4. The display device according to claim 2, wherein the light emitting element layer comprises:
a first electrode disposed in the emission area;
the light emitting layer disposed on the first electrode;
a second electrode disposed on the light emitting layer; and
a low reflection layer disposed on the second electrode of the display area and including at least one of bismuth (Bi) or ytterbium (Yb).

5. The display device according to claim 4, wherein the shielding layer further includes a reflection adjusting layer including a dye or a pigment that absorbs light of a preset wavelength area.

6. The display device according to claim 5, wherein the reflection adjusting layer covers at least a portion of the black matrix and the shielding electrode.

7. The display device according to claim 5, wherein the reflection adjusting layer absorbs light of a wavelength range of about 490 nm or more and about 500 nm or less and a wavelength range of about 500 nm or more and about 600 nm or less.

8. The display device according to claim 2, wherein a color of the pixel defining layer is black.

9. The display device according to claim 1, wherein the display panel comprises:
a pixel circuit disposed between the substrate and the light emitting element layer and configured to drive the light emitting element layer; and
pads disposed on the non-display area of the substrate and electrically connected to the pixel circuit.

10. The display device according to claim 9, wherein the shielding electrode extends to the non-display area and is electrically connected to a portion of the pads.

11. The display device according to claim 10, wherein the shielding electrode contacts the portion of the pads through a contact hole.

12. The display device according to claim 10, wherein first power or second power provided to the pixel circuit is supplied to the shielding electrode.

13. The display device according to claim 9, wherein the touch panel comprises:
a first touch electrode layer disposed on the first optically clear adhesive;
an insulating film disposed on the first touch electrode layer; and
a second touch electrode layer disposed on the insulating film and forming the touch electrodes together with the first touch electrode layer.

14. The display device according to claim 13, wherein the touch panel further includes touch pads overlapping the non-display area and connected to the first touch electrode layer or the second touch electrode layer.

15. The display device according to claim 1, wherein the touch electrodes include a transparent conductive material overlapping the emission area and the non-emission area.

16. The display device according to claim 1, wherein the shielding layer further comprises:
an insulating layer disposed between the thin film encapsulation layer and the shielding electrode; and
a passivation layer covering at least a portion of the shielding electrode.

17. The display device according to claim 1, further comprising:
a polarizer disposed between the shielding layer and the touch panel.

18. The display device according to claim 1, further comprising:
a polarizer attached to the touch panel through a second optically clear adhesive.

19. A display device comprising:
a display panel including a light emitting element layer including a pixel defining layer dividing a display area into a first area and a second area, a thin film encapsulation layer disposed on the light emitting element layer, and a shielding layer including a shielding electrode disposed on the thin film encapsulation layer that is disposed on a substrate including the display area and a non-display area;
a polarizer disposed on the shielding layer; and
a touch panel attached to the polarizer through an optically clear adhesive and including touch electrodes,
wherein the light emitting element layer includes a light emitting layer corresponding to the first area,
the touch electrodes overlap the first area and the second area, and
the shielding electrode includes an opaque metal and overlaps the second area.

20. The display device according to claim 19, wherein the display panel comprises:
a pixel circuit disposed between the substrate and the light emitting element layer and configured to drive the light emitting element layer; and
pads disposed on the non-display area of the substrate and electrically connected to the pixel circuit,
wherein the shielding electrode extends to the non-display area and is electrically connected to a portion of the pads, and
first power or second power provided to the pixel circuit is supplied to the shielding electrode.
